(19) United States
(12) Patent Application Publication
(10) Pub. No.: US 2025/0226312 A1
(43) Pub. Date: Jul. 10, 2025

(54) CIRCUIT STRUCTURE

(71) Applicant: SILICONWARE PRECISION INDUSTRIES CO., LTD., Taichung City (TW)

(72) Inventors: Hsing-Yu LIU, Taichung City (TW); Wei-Son TSAI, Taichung City (TW); Kun-Yuan LUO, Taichung City (TW); Pei-Geng WENG, Taichung City (TW)

(21) Appl. No.: 18/768,791

(22) Filed: Jul. 10, 2024

(30) Foreign Application Priority Data
Jan. 4, 2024 (TW) 113100440

(51) Int. Cl. H01L 23/528; H01L 23/522

(52) U.S. Cl. CPC H01L 23/528; H01L 23/5226

(57) ABSTRACT

The present disclosure provides a circuit structure having an insulating layer; a plurality of first circuits disposed on one side of the insulating layer; and a plurality of first electrical connection pads, each having a first extension portion extending toward and electrically connected to one end of a first circuit of the first circuits, wherein a width of the extension portion gradually decreases toward a junction of the first extension portion and the first circuit. By implementing of the present disclosure, stress on the junction between the electrical connection pad and the circuit can be dispersed along the extension portion through the arrangement of the extension portion and its tapered width design, thereby preventing fracture on the junction of the electrical connection pad and the circuit due to excessively concentrated stress, so that the manufacturing yield and reliability of semiconductor packages with this circuit structure can be improved.

### CROSS-REFERENCE TO RELATED APPLICATIONS

The present application is based upon and claims the right of priority to TW Patent Application No. 113100440, filed Jan. 4, 2024, the disclosure of which is hereby incorporated by reference herein in its entirety for all purposes.

### BACKGROUND

### 1. Technical Field

The present disclosure relates to a circuit structure, and more particularly, to a circuit structure of a semiconductor device.

### 2. Description of Related Art

With the explosive growth of today's information volume, the demand for technologies and/or equipment such as High Performance Computing (HPC) and various servers has also increased rapidly, resulting in an increase in the number and density of components integrated within the semiconductor devices used as the cores of these equipment are also increasing. At the same time, the signal transmission paths between the components within the semiconductor devices must be somehow shortened to accelerate the transmission and processing speed for the data. In addition, the power consumption and heat generation also have to be reduced to facilitate further miniaturization of semiconductor devices. To this end, various stacked packaging technologies such as 2.5D packaging, 3D packaging, etc., as well as multi-layer circuit architectures such as Redistribution Layer (RDL) have been continuously introduced and widely used.

However, in conventional packages, due to problems such as different coefficient of thermal expansion between an insulating layer/substrate, circuits and components, warpage and other deformation problems occur in the package during the manufacturing process. These warpage and deformation problems further lead to the generation and accumulation of stress, causing track crack in each circuit layer as the decrease of trace width, especially where the traces are in connection with the connection pads used to electrically connect various components or conductive vias. FIG. 1A is a partial top view of one end portion of a circuit in a conventional semiconductor package. As shown in the figure, since a width of a connection pad 13 is usually larger than a width of a trace 12, a significant width difference is formed at a junction of these two parts. A location where this significant width difference occurs is generally the weakest structural strength of an entire conductive path composed of the connection pad 13 and the trace 12. If a warpage of the package (not shown) occurs at this time, the stress generated by the warpage will easily cause crack at the junction between the circuit 12 and the connection pad 13, as shown in FIG. 1A.

The aforementioned problems are more serious in multi-layer stacked packages. FIG. 1B is a partial cross-sectional view of an end portion of a circuit in a conventional semiconductor package. In a multi-layer stacked package, since conductive vias 14 are generally used to provide electrical connection between the traces 12 of different layers located on both sides of an insulating layer 11, the traces 12 and/or components (not shown) of each layer connected to the conductive vias 14 are gathered in an area A near the conductive vias 14. Thus, the stresses generated as thermal deformation and other problems occur in the layers within the area A are accumulated vertically along a direction of extension of the conductive via 14, so that the crack of the junction of the electrical connection pad 13 and the circuit 12 in the area occurs more easily, eventually leading to the failure of the semiconductor package. This not only causes a decrease in yield during manufacturing, but also makes the semiconductor package to be easily damaged due to thermal deformation caused by the heat generated during operation in subsequent practical applications, resulting in poor product reliability.

Therefore, how to overcome the above-mentioned problems of conventional techniques has become an urgent issue to be solved.

### SUMMARY

In view of the various shortcomings of the prior art, the present disclosure provides a circuit structure, which comprises: an insulating layer; a plurality of first circuits disposed on a surface at one side of the insulating layer; and a plurality of first electrical connection pads, each of which has a first extension portion extending toward and electrically connected to one end of a first circuit of the first circuits, wherein a width of each of the first electrical connection pads in a direction transverse to the first circuit connected thereto is wider than a width of the first circuit, and a width of the first extension portion gradually decreases toward a junction of the first extension portion and the first circuit.

In the aforementioned circuit structure, the first extension portion has a first extension angle θ1 formed between edges on both sides of the first circuit connected to the first extension portion, and the first extension angle θ1 is less than 90°.

In the aforementioned circuit structure, an extension path of each of the first circuits differs from a virtual straight line connecting two ends of the first circuit.

In the aforementioned circuit structure, a path length of each of the first circuits is greater than a straight-line distance between the two ends of the first circuit.

In the aforementioned circuit structure, which further comprises: a plurality of second circuits disposed on another side of the insulating layer; a plurality of second electrical connection pads, each of which has a second extension portion extending toward and electrically connected to one end of a second circuit of the second circuits, wherein a width of each of the second electrical connection pads in a direction transvers to the second circuit connected thereto is greater than a width of the second circuit, and a width of the second extension portion gradually decreases toward a junction of the second extension portion and the second circuit connected thereto; and a plurality of first conductive vias disposed in the insulating layer and penetrating the insulating layer, wherein two ends of each of the first conductive vias correspond to and electrically connected respectively to one of the first electrical connection pads and one of the second electrical connection pads.

In the aforementioned circuit structure, the second extension portion has a second extension angle θ2 formed between edges on both sides of the second circuit connected to the second extension portion, and the second extension angle θ2 is less than 90°.

In the aforementioned circuit structure, the first extension portion of the one of the first electrical connection pads and the second extension portion of the one of the second electrical connection pads connected respectively to the two ends of each of the first conductive vias extend in different directions.

In the aforementioned circuit structure, an extension path of each of the second circuits differs from a virtual straight line connecting two ends of the second circuit.

In the aforementioned circuit structure, a path length of each of the second circuits is greater than a straight-line distance between the two ends of the second circuit.

In the aforementioned circuit structure, the first circuit electrically connected to the one of the first electrical connection pads and the second circuit electrically connected to the one of the second electrical connection pads at the two ends of each of the first conductive vias, respectively, extend along different directions on different surfaces of the insulating layer.

It can be seen from the above, by providing an extension portion at electrical connection pad in a circuit structure and rendering the extension portion has a gradually decreasing width toward a circuit electrically connected to the electrical connection pad, no sudden changes in width of the conductive material forming these electrical connection pad and circuit occur at an junction thereof, so that the stresses exerted on the junctions of the electrical connection pads and the circuits due to various deformation problems can be gradually dispersed along the extension direction of the extension portion, thereby avoiding the occurrence of crack in the conductive path/material at these connection positions. Therefore, it can effectively improve the manufacturing yield of semiconductor packages with this circuit structure and the reliability in subsequent use.

### BRIEF DESCRIPTION OF THE DRAWINGS

FIG. 1A is a partial top view of one end portion of a circuit in a conventional semiconductor package.

FIG. 1B is a partial cross-sectional view of an end portion of a circuit in a conventional semiconductor package.

FIG. 2A is a partial cross-sectional view of a circuit structure according to the first embodiment of the present disclosure.

FIG. 2B is a partial top view of a circuit structure according to the first embodiment of the present disclosure.

FIGS. 2C and 2D are partial top views of two different variant aspects according to the first embodiment of the present disclosure.

FIG. 3A is a partial cross-sectional view of a circuit structure according to the second embodiment of the present disclosure.

FIG. 3B is a partial perspective view of the second embodiment according to the circuit structure of the present disclosure.

FIG. 3C is a partial top view of a circuit structure according to the second embodiment of the present disclosure.

FIG. 3D is a partial top view of a variant aspect according to the second embodiment of the present disclosure.

FIG. 4 is a partial cross-sectional view of a circuit structure according to the third embodiment of the present disclosure.

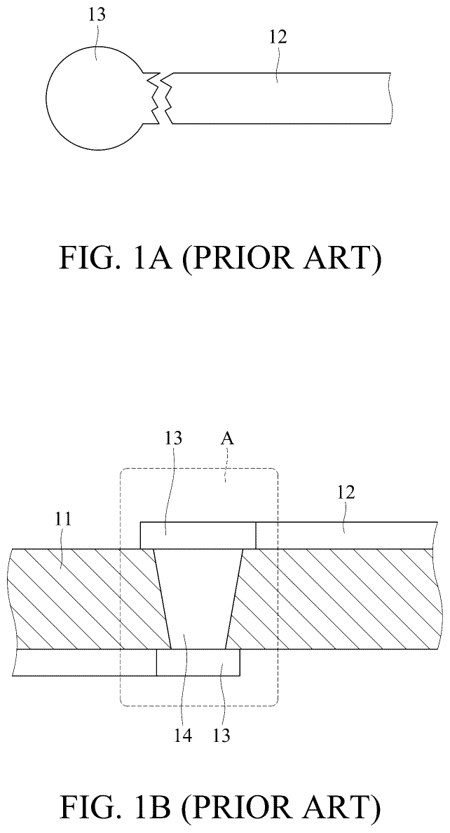

### DETAILED DESCRIPTION

Embodiments of the present disclosure are illustrated with the following examples. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

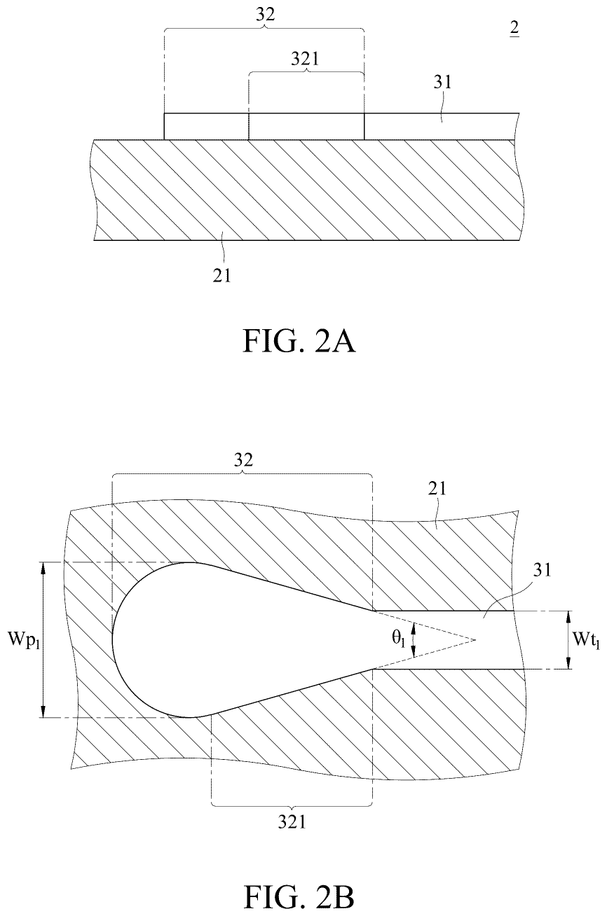

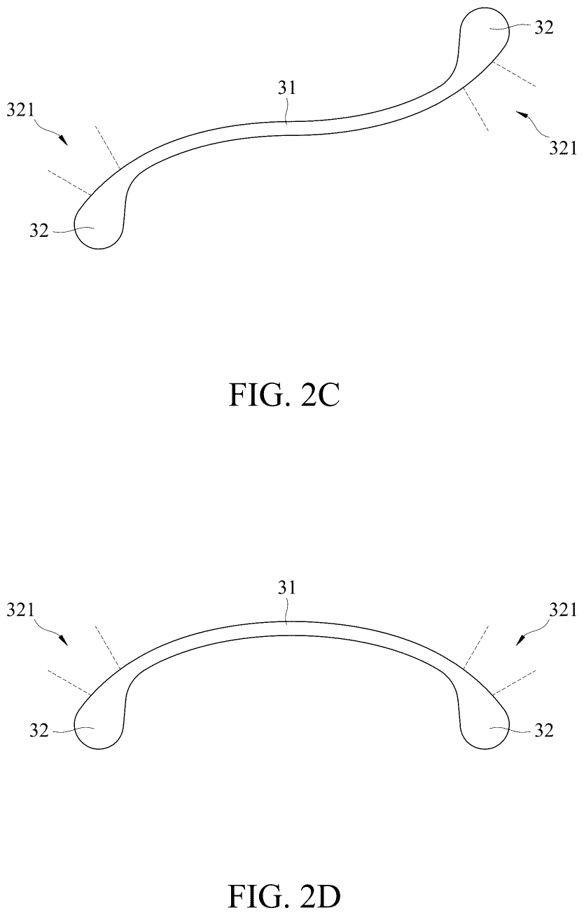

FIG. 2A and FIG. 2B are a partial cross-sectional view and a partial top view of a circuit structure according to an embodiment of the present disclosure, respectively. As shown in the figures, a circuit structure 2 comprises: an insulating layer 21, a plurality of first circuits 31 disposed on a surface of one side of the insulating layer 21, and a plurality of first electrical connection pads 32.

The insulating layer 21 is usually a dielectric layer in a semiconductor device. As such, the material of the insulating layer 21 is usually made of dielectric material, such as polybenzoxazole (PBO), polyimide (PI), prepreg, etc. However, it can also be any other insulating material that meets the requirements, and this embodiment is not limited thereto.

A plurality of first circuits 31 are disposed on a surface of one side of the insulating layer 21, and only one of them is shown as an example in FIG. 2A and FIG. 2B. Each of the first circuits 31 is usually made of copper, aluminum or other metals, but other conductive materials can also be used, and this embodiment is not limited thereto.

A plurality of first electrical connection pads 32 are also disposed on the surface of the insulating layer 21, and only one of them is shown in FIG. 2A and FIG. 2B as an example. Each of the first electrical connection pads 32 individually has a first extension portion 321 extending toward one end of one of the first circuits 31 and electrically connected thereto. A width Wp1 of the first electrical connection pad 32 in a direction transverse to the first circuit 31 connected thereto is larger than a width Wt1 of the first circuit 31, and a width of the first extension portion 321 of the first electrical connection pad 32 gradually decreases toward a junction of the first electrical connection pad 32 and the first circuit 31 until the junction of the first electrical connection pad 32 and the first circuit 31. At this point, the width of the first extension portion 321 of the first electrical connection pad 32 is equal to the width Wt1 of the first circuit 31.

Due to this design of each first electrical connection pad 32 having a first extension portion 321 which extends toward its junction with the first circuit 31 and gradually decreases in width, no sudden changes in width of the conductive material forming the first electrical connection pad 32 and the first circuit 31 occur at each junction of the first electrical connection pad 32 and the first circuit 31. Thus, even if warpage or other deformation occurs in the circuit structure 2 in this embodiment, the stress generated can be gradually distributed along the first extension portion 321, thereby avoiding uneven distribution of stress concentrated in a small area and consequently causing fracture of the conductive material at that area.

More specifically, the first extension portion 321 has a tapered shape such that the first extension portion 321 has a first extension angle θ1 formed between the edges on both sides of the first circuit 31 connected to it, and the first extension angle θ1 is less than 90°. It can be understood that the smaller the first extension angle θ1 is, the longer the length of the first extension portion 321 extends, and the larger the area used for stress dispersion, and more effective it is in preventing fracture. In practical applications, the size and setting of the first extension angle θ1 need to consider factors such as the stress to be dispersed and the area to be occupied.

For clarity, the insulating layer 21 is omitted and not shown in both FIG. 2C and FIG. 2D. As shown in FIG. 2C and FIG. 2D, in addition to each first electrical connection pad 32 having a first extension portion 321, the first circuit 31 is also designed to extend along a path that differs from a virtual straight line connecting both ends thereof. In other words, an extending path of the first circuit 31 is designed to have a nonlinear shape. In an aspect of the embodiment shown in FIG. 2C, two curved traces in opposite bending directions are connected each other to form a first circuit 31, while in an aspect of the embodiment shown in FIG. 2D, the first circuit 31 is completely biased to one side of the virtual straight line connecting the two ends of the first circuit 31. These curve designs allow the first circuit 31 and the first electrical connection pads 32 connected thereto to have a spring-like function, and can be adapted to deformation when deformation occurs, so as to absorb the stress caused by the deformation.

In practice, the path that differs from the virtual straight line connecting the two ends of the first circuit 31 may have any shape and is not limited to the aspects of the embodiment shown in FIG. 2C and FIG. 2D. However, in viewing of factors such as the limited area and increasingly higher component density within a semiconductor package, the actual shape used usually does not deviate too much from the virtual straight line. It is understandable that the path length of such first circuit 31 is longer than the straight-line distance between the two ends of the first circuit 31.

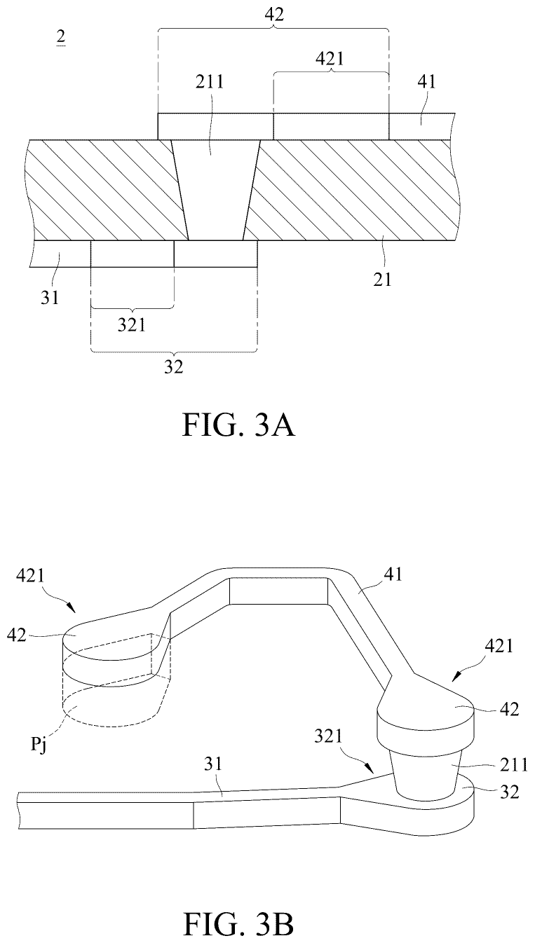

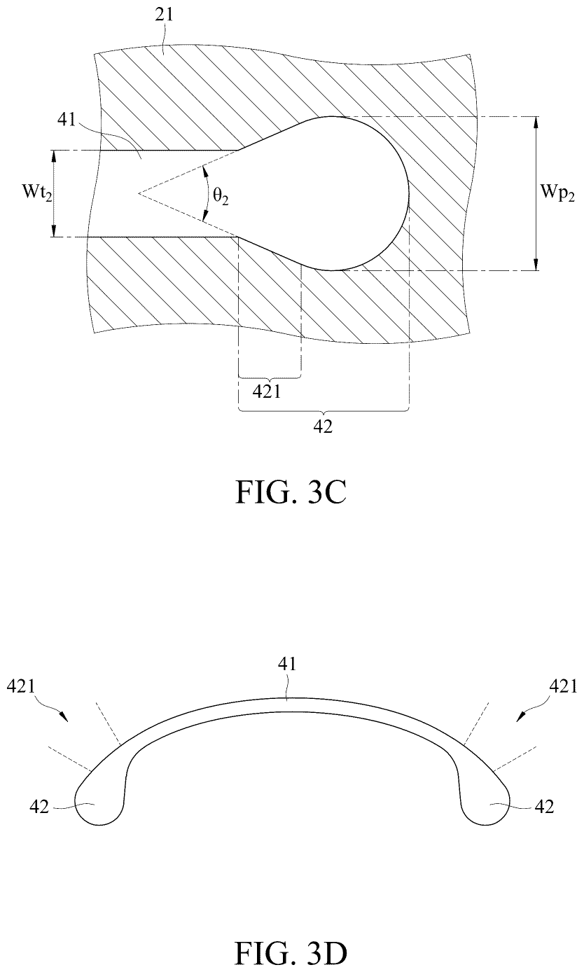

Furthermore, in addition to the single-layer structure described above, the circuit structure 2 provided by the present disclosure may also be applied to a multi-layer structure. As shown in the second embodiment of the present disclosure illustrated in FIG. 3A to FIG. 3C, the circuit structure 2 may further comprise: a plurality of second circuits 41, a plurality of second electrical connection pads 42, and a plurality of first conductive vias 211. It should be noted that in FIG. 3B, in order to more clearly show the relative positions and connection relationship between the first circuit 31, the first electrical connection pad 32, the first conductive via 211, the second circuit 41, and the second electrical connection pad 42, the insulating layer 21 is omitted and not shown, and the first circuit 31, the first electrical connection pad 32 (including the first extension portion 321), the first conductive via 211, the second circuit 41, and the second electrical connection pad 42 (including the second extension portion 421) are each shown only one as an example.

The second circuits 41 and the second electrical connection pad 42 are arranged on a surface of another side of the insulating layer 21 opposite the first circuit 31, and can together form, for example, a redistribution layer (RDL), but is not limited to this. Similarly, the second circuit 41 and the second electrical connection pad 42 are also made of conductive materials such as copper or other metals, without any special limitation. Each second electrical connection pad 42 has a second extension portion 421 extending toward one end of a second circuit 41 and electrically connected to the second circuit 41 (see FIG. 3C), and each second electrical connection pad 42 has a width Wp2 in a direction transverse to the second circuit 41 connected thereto. The width Wp2 is larger than a width Wt2 of the second circuit 41. In the meanwhile, the width of the second extension portion 421 of each second electrical connection pad 42 gradually decreases toward a junction of the second electrical connection pad 42 and the second circuit 41 connected thereto until the junction of the second electrical connection pad 42 and the circuit connected thereto.

The second extension portion 421 of each second electrical connection pad 42 has a second extension angle θ2 formed between the edges on both sides of the second circuit 41 to which it is connected, and the second extension angle θ2 is less than 90°. These technical details and functional mechanisms of the second circuit 41, the second electrical connection pad 42 and the second extension portion 421 are the same as those of the first circuit 31, the first electrical connection pad 32 and the first extension portion 321, so as not to be described repeatedly herein.

Furthermore, in some embodiments, in order to electrically connect the first circuit 31 and a second circuit 41 located on the two sides of the insulating layer 21, a first conductive via 211 penetrating the insulating layer 21 may be formed in the insulating layer 21, and both ends of the first conductive via 211 correspond to and are electrically connected to a first electrical connection pad 32 and a second electrical connection pad 42, respectively.

In order to more effectively alleviate effect of the stresses on each junction of the first circuit 31 and first electrical connection pad 32 and of the second circuit 41 and the second electrical connection pad 42 in the circuits in each individual layer as they encounter the thermal deformations, in particular, the stresses on the upper and lower surfaces of the insulating layer 21 occur at the corresponding positions of the two surfaces, causing the stresses to be superimposed. The first extension portion 321 of the first electrical connection pad 32 and the second extension portion 421 of the second electrical connection pad 42 connected respectively to the two ends of each the first conductive via 211 extend in different directions on the individual surface of the insulating layer 21 where they are located respectively, such that as the junction of the second extension portion 421 of the second electrical connection pad 42 and the second circuit 41 is projected onto the other surface of the insulating layer 21, the location of the projection Pj of the second electrical connection pad 42 including its second extension portion 421 and the junction of it and the second circuit 41 on the other surface of the insulating layer 21 deviates from the junction of the first extension portion 321 of the first electrical connection pad 32 and the first circuit 31, and vice versa. Since the junction of each electrical connection pad and the circuit is generally the location where the stress is greater or even the maximum, the structural arrangement of staggering the locations where the stresses in/on different layers/surfaces are greater can make the locations on the two opposite surfaces of the insulating layer 21, that are subjected to greater stresses in the conductive paths, not correspond to each other, so as to avoid the superposition of stresses acting on the upper and lower surfaces and causing conductive paths in/on the layers/surfaces in this area to crack.

As shown in FIG. 3D, in a modified embodiment, the extension path of each second circuit 41 can also be designed not to be on a virtual straight line connecting the two ends of the second circuit 41 and to be different from the virtual straight line. The shape of the extension path of each second circuit 41 also has no special restrictions. In this aspect of embodiment, the path length of each second circuit 41 is also greater than the straight-line distance between its two ends. The technical details and advantages of this type of aspect have been mentioned above, and so as not to be described repeatedly herein.

In another aspect of the embodiment, the first circuit 31 electrically connected to the first electrical connection pad 32 and the second circuit 41 electrically connected to the second electrical connection pad 42 located at the two ends of the first conductive via 211, respectively, extend in different directions along different surfaces of the insulating layer 21. That is, at the two ends of each first conductive via 211, not only the first extension portion 321 of the first electrical connection pad 32 and the second extension portion 421 of the second electrical connection pad 42 extend in different directions, but also the first circuit 31 connected to the first electrical connection pad 32 and the second circuit 41 connected to the second electrical connection pad 32 also extend in different directions along different surfaces of the insulating layer 21. This is more effectively prevent the conductive path/material from breaking.

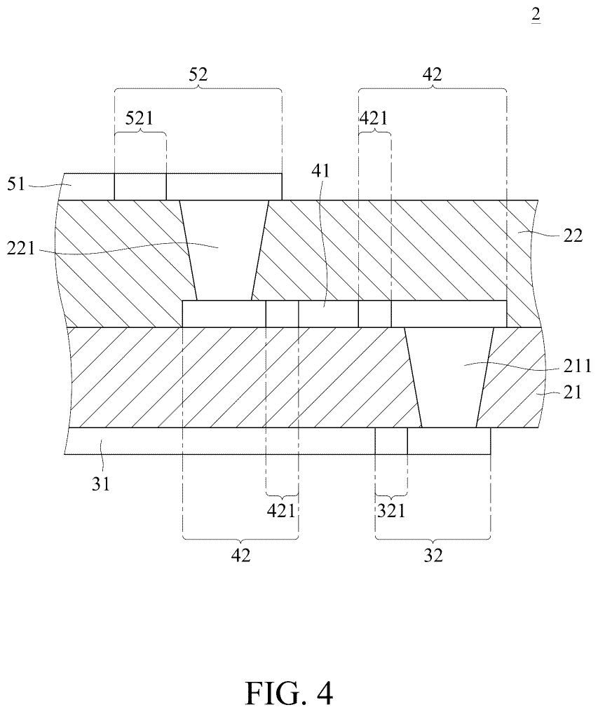

As shown in FIG. 4, in addition to the above aspect with only one insulating layer 21, the circuit structure 2 provided by the present disclosure may also be applied in a multi-layer structure. For instance, a second insulating layer 22 may be added on the top side of the insulating layer 21, the second circuit 41 and the second electrical connection pad 42, and a plurality of third circuits 51 and a plurality of third electrical connection pads 52 may also be disposed on the surface of the top side of the second insulating layer 22, and meanwhile second conductive vias 221 penetrating through the second insulating layer 22 may be formed in the second insulating layer 22.

Those third circuits 51 and the third electrical connection pads 52 are all located on the surface of the top side of the second insulating layer 22, and each third electrical connection pad 52 has a third extension portion 521 extending toward a third circuit 51 and electrically connected thereto.

The second conductive via 221 is used to electrically connect a second electrical connection pad 42 and a third electrical connection pad 52, thereby enabling the second circuit 41 to be electrically connected to the third circuit 51. All the relative positions and connection relationships between the third circuits 51, the third electrical connection pads 52 and the second conductive vias 221 and between the second circuits 41, the second electrical connection pads 42 and the second conductive vias 221 all can utilize the same technical concepts as those in the above embodiments, and the same effect can be achieved to avoid breakage of conductive paths in each layer in a multi-layer structure, so no further description is given.

To sum up, by providing the first extension portion, the second extension portion and the third extension portion at end portions of the circuits including the first, second, and third circuits and the first, second, and third electrical connection pads electrically connected thereto, and rending the first, second and third extension portions each have a gradually decreasing width toward junctions of the first, second, and third circuits and the first, second, and third electrical connection pads connected thereto, the present disclosure can avoid the occurrence of rapid and tremendous variance in the width of the conductive materials forming these circuits and electrical connection pads to cause structural weaknesses. In addition, each circuit is not laid along the virtual straight line connecting its two ends, so that when the circuit structure provided by the present disclosure encounters the warpage condition of each insulating layer, the stress generated can be dispersed along each extension portion, or be absorbed through compliance by the non-linear structure, such that the conductive paths composed of each circuit and each electrical connection pad included in the circuit structure are not be broken. Furthermore, by making the extension portion of each of the electrical connection pads that connects to the two ends of each conductive via and located in different layers, and the first circuits, the second circuits and the third circuits connected to those electrical connection pads, respectively, extend in different directions to avoid vertically adding the stresses caused by the deformations of different layers up, the effect of preventing the conductive paths of each layer of the circuit structure from cracking can be further improved, thereby improving manufacturing yield and reliability of the semiconductor packages having the circuit structure provided by the present disclosure.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. A circuit structure, comprising:
an insulating layer;
a plurality of first circuits disposed on a surface at one side of the insulating layer; and
a plurality of first electrical connection pads, each of which has a first extension portion extending toward and electrically connected to one end of a first circuit of the first circuits, wherein a width of each of the first electrical connection pads in a direction transverse to the first circuit connected thereto is wider than a width of the first circuit, and a width of the first extension portion gradually decreases toward a junction of the first extension portion and the first circuit connected thereto.

2. The circuit structure of claim 1, wherein the first extension portion has a first extension angle θ1 formed between edges on both sides of the first circuit connected to the first extension portion, and the first extension angle θ1 is less than 90°.

3. The circuit structure of claim 1, wherein an extension path of each of the first circuits differs from a virtual straight line connecting two ends of the first circuit.

4. The circuit structure of claim 3, wherein a path length of each of the first circuits is greater than a straight-line distance between the two ends of the first circuit.

5. The circuit structure of claim 1, further comprising:
a plurality of second circuits disposed on another side of the insulating layer;
a plurality of second electrical connection pads, each of which has a second extension portion extending toward and electrically connected to one end of a second circuit of the second circuits, wherein a width of each of the second electrical connection pads in a direction transverse to the second circuit connected thereto is greater than a width of the second circuit, and a width of the second extension portion gradually decreases toward a junction of the second extension portion and the second circuit connected thereto; and
a plurality of first conductive vias disposed in the insulating layer and penetrating the insulating layer, wherein two ends of each of the first conductive vias correspond to and electrically connected respectively to one of the first electrical connection pads and one of the second electrical connection pads.

6. The circuit structure of claim 5, wherein the second extension portion has a second extension angle θ2 formed between edges on both sides of the second circuit connected to the second extension portion, and the second extension angle θ2 is less than 90°.

7. The circuit structure of claim 5, wherein the first extension portion of the one of the first electrical connection pads and the second extension portion of the one of the second electrical connection pads connected respectively to the two ends of each of the first conductive vias extend in different directions.

8. The circuit structure of claim 5, wherein an extension path of each of the second circuits differs from a virtual straight line connecting two ends of the second circuit.

9. The circuit structure of claim 8, wherein a path length of each of the second circuits is greater than a straight-line distance between the two ends of the second circuit.

10. The circuit structure of claim 5, wherein the first circuit electrically connected to the one of the first electrical connection pads and the second circuit electrically connected to the one of the second electrical connection pads at the two ends of each of the first conductive vias, respectively, extend along different directions on different surfaces of the insulating layer.
